(19) United States
(12) Patent Application Publication
(10) Pub. No.: US 2024/0282979 A1
(43) Pub. Date: Aug. 22, 2024

(54) SEPARATOR FOR FUEL CELL WITH METAL COATING LAYER AND MANUFACTURING METHOD THEREFOR

(71) Applicant: Hyundai Steel Company, Incheon (KR)

(72) Inventors: Hyun Uk Im, Incheon (KR); Kun Ho Kim, Incheon (KR); Kwang Seo Park, Incheon (KR); Jae Ho Lee, Incheon (KR); Yeon Soo Jeong, Incheon (KR)

(21) Appl. No.: 18/654,563

(22) Filed: May 3, 2024

(30) Foreign Application Priority Data
Nov. 4, 2021 (KR) 10-2021-0150245

(51) Int. Cl. H01M 8/0206; C23C 14/58; H01M 8/0228; H01M 8/0267

(52) U.S. Cl. CPC H01M 8/0206; C23C 14/5806; H01M 8/0228; H01M 8/0267; H01M 2250/20

(57) ABSTRACT

A method for manufacturing a metal separator for a vehicle fuel cell according to an aspect of the present disclosure comprises the steps of: preparing a base material; applying a platinum (Pt)-containing coating agent and an electrolyte to the base material to form a discontinuous coating film; and thermally treating the coating film-formed base material.

### CROSS-REFERENCE TO RELATED APPLICATION

This application claims the benefit of PCT application PCT/KR2022/017131, filed on Nov. 3, 2022, which claims the benefit of Korean Patent Application No. 10-2021-0150245, filed in the Korean Intellectual Property Office on Nov. 4, 2021, all of which are incorporated herein by reference.

### BACKGROUND

### Technical Field

The present disclosure relates to a separator for a fuel cell with metal coating layer and a manufacturing method therefor, and more particularly, to a separator for a fuel cell on which a discontinuous coating layer is formed, using platinum and precious metals, and a manufacturing method.

### Background

Fuel cells used in hydrogen electricity are utilized as a power source generating electricity through an electrochemical reaction between a reaction gas and a catalyst. A cell stack of the fuel cell has a structure in which components such as a membrane electrode assembly (MEA), a separator (or a bipolar plate), a gasket, a current collector, and an end plate are connected to each other. Among these components, the membrane electrode assembly (MEA) has a structure in which gas diffusion electrodes (GDEs) each including a catalyst layer and a gas diffusion layer (GDL) are in contact with both sides of a polymer electrolyte member with the polymer electrolyte membrane interposed therebetween.

A metal separator for a fuel cell is one of the components that constitute the stack of the fuel cell and is in electrical contact with a hydrogen electrode of a unit cell and an air electrode of an adjacent cell, where hydrogen and air are supplied into each electrode through a fluid flow channel on both sides of the separator. Therefore, the metal separator of a fuel cell collects and transmits electricity generated from electrochemical reactions, and plays a key role in conducting electricity, discharging water formed by electrical reactions, and managing heat inside a battery.

A material with excellent electrical conductivity, such as stainless steel, titanium alloy, aluminum alloy, or polymer composite material, is used as the base material of the separator. However, when the separator is exposed to an operating environment of the fuel cell for a vehicle in which a temperature and a humidity are high for a long time, due to characteristics of the metal, corrosion is accelerated, and metal oxide formed on a surface of the base material of the separator acts as an electrical insulator to decrease overall performance of the fuel cell due to decrease of conductivity or contamination of the catalyst.

In order to prevent these problems, research into technology of securing corrosion resistance and improving conductivity by forming a discontinuous coating layer containing a polymer, carbon, and various precious metal materials including gold (Au), platinum (Pt), ruthenium (Ru), iridium (Ir), etc., on the surface of the base material of the metal separator has been conducted, but in practice, a coating layer using a gold (Au) nano-coating layer has been mainly used. However, due to a continuous increase in price of gold (Au), the necessity to develop an alternative coating layer has emerged.

Furthermore, experiments or studies have previously been conducted showing that a discontinuous platinum (Pt) coating layer may be formed on a surface of the base material. However, the results showing process efficiency and clear significance in application of the coating layer using platinum are insufficient.

When the discontinuous coating layer is applied, a part of the surface of the base material of the separator is directly exposed to the outside. For future fuel cell stacks that require high output and long durability, coating technology with excellent conductivity and chemical stability is required even when used in harsh environments, despite the fact that a lot of resources are required to ensure performance due to coating uniformity of new coating materials and to verify the stability of a plated electrode body.

Related technology is disclosed in Korean Patent Laid-Open Publication No. 10-2015-0138105 (published on Apr. 7, 2017, entitled “COATING COMPOSITION FOR METAL SEPARATOR OF SOLID OXIDE FUEL CELL AND PREPARATION METHOD THEREFOR”).

### SUMMARY

One of the problems to be solved by the present disclosure is to provide a metal separator of a fuel cell for a vehicle with excellent corrosion resistance and contact resistance, as well as excellent production efficiency, and a manufacturing method therefor.

A method for manufacturing a metal separator of a fuel cell for a vehicle according to one embodiment of the present disclosure may include: preparing a base material; applying a platinum (Pt)-containing coating agent and an electrolyte on the base material to form a discontinuous coating layer; and thermally treating the base material and the coating layer to form on an oxide layer on the base material.

The platinum (Pt)-containing coating agent may further include gold (Au), ruthenium (Ru), iridium (Ir), ruthenium oxide (RuO₂), or iridium oxide (IrO₂).

In an exemplary embodiment, the base material may be stainless steel, titanium, aluminum or polymer composite material.

In an exemplary embodiment, the step of forming of the discontinuous coating layer may be performed through electroplating, electroless plating, or a PVD process.

In an exemplary embodiment, chloroplatinic acid (H₂PtCl₆) or potassium chloroplatinate (K₂PtCl₆) may be contained as platinum (Pt) contained in the platinum (Pt)-containing coating agent.

In an exemplary embodiment, the step of thermally treating may be performed in a temperature range of about 80 to 600° C. In an exemplary embodiment wherein the base material is stainless steel, the step of thermally treating is performed in a temperature range of about 170 to 230° C. In an exemplary embodiment wherein the base material is titanium, the step of thermally treating is performed in a temperature range of about 300 to 500° C.

In an exemplary embodiment, the step of thermally treating may be performed in a time range of about 10 to 180 minutes or about 30 to 60 minutes.

In an exemplary embodiment, the step of thermally treating may be performed under vacuum, air, or oxygen atmosphere.

In an exemplary embodiment, the electrolyte may be an acidic electrolyte. The acidic electrolyte may be a sulfuric acid-based or hydrochloric acid-based electrolyte. The sulfuric acid-based electrolyte may be H₂SO₄. The hydrochloric acid-based electrolyte may be HCIO₄.

In an exemplary embodiment, the step of applying a platinum (Pt)-containing coating agent and an electrolyte on the base material may include applying a current at a coating temperature. The current may be about 5 to 60 mA/cm² and the coating temperature may be about 25 to 80° C.

The metal separator of a fuel cell for a vehicle according to another embodiment of the present disclosure may be a metal separator of a fuel cell for a vehicle manufactured by any one of the above-described embodiments. As discussed, the method and system suitably include use of a controller or processer.

In another embodiment, vehicles are provided that comprise an apparatus as disclosed herein.

According to the present disclosure, a metal separator for a fuel cell with excellent corrosion resistance and contact resistance, as well as excellent production efficiency, and a manufacturing method therefor may be provided.

### BRIEF DESCRIPTION OF THE DRAWINGS

FIG. 1 is a process flow diagram schematically illustrating a method for manufacturing a separator for a fuel cell according to an exemplary embodiment of the present disclosure.

FIG. 2 is a diagram schematically illustrating a step of coating platinum according to an Example of the present disclosure and Comparative Example.

FIG. 3 is a diagram schematically illustrating a step of thermal treatment according to an Example of the present disclosure and Comparative Example.

FIG. 4 is a schematic diagram for explaining specimens and measurement positions for measuring contact resistance of Examples and Comparative Examples of the present disclosure.

### DETAILED DESCRIPTION

Hereinafter, the present disclosure will be described in detail to enable those skilled in the art to which the invention belongs to readily practice the invention with reference to the accompanying drawings. The present disclosure may be implemented in many different forms and is not limited to the embodiments described herein. Throughout the specification, identical or similar components are indicated by the same reference numerals. In addition, detailed descriptions of known functions and configurations that may unnecessarily obscure the gist of the present disclosure are omitted.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within two standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

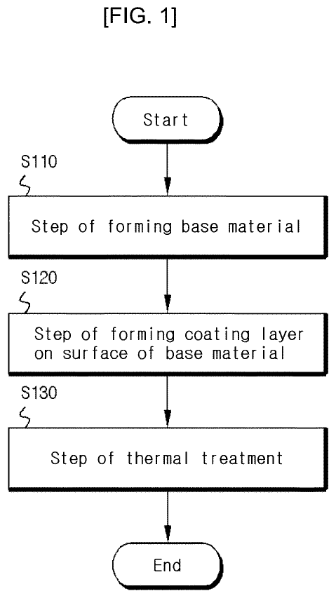

FIG. 1 is a flow diagram used in a method for manufacturing of a metal separator of a fuel cell for a vehicle according to an exemplary embodiment of the present disclosure. The manufacturing method according to the present disclosure includes a step of forming base material (S110), a step of forming coating layer on a surface of base material (S120), and a step of thermal treatment (S130).

### Step of Forming Base Material (S110)

There is no particular limitation on the steel of the metal separator of a fuel cell for a vehicle, as long as it is a metal or non-ferrous metal for this application. Materials such as stainless steel, titanium, and aluminum, may be used. For example, SUS 300-series and 400-series stainless steel or Grade 1 titanium may be preferred due to their superior elongation properties and durability.

### Step of Forming Coating Layer on Surface of Base Material (S120)

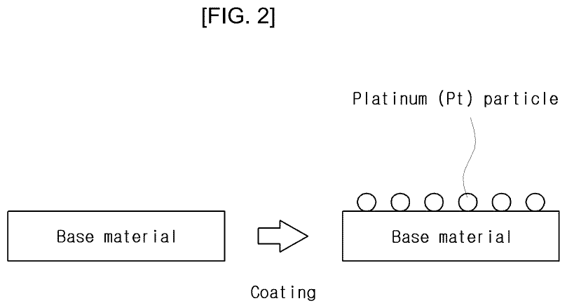

FIG. 2 schematically illustrates of a step of forming a coating layer containing discontinuous platinum on a surface of the base material.

When the fuel cell for a vehicle is exposed to a high-temperature and humid operating environment for an extended period of time, metal oxides that gradually adversely affect the conductivity of the fuel cell form on the surface of the base material. Therefore, in the present disclosure, a discontinuous coating layer is formed on the surface of the base material to enhance the fuel cell's corrosion resistance and conductivity.

In order to form a coating layer with both excellent corrosion resistance and conductivity, a range of precious metals including gold (Au), platinum (Pt), ruthenium (Ru), and iridium (Ir) are typically used. The present disclosure may form a coating layer of a metal separator of a fuel cell of for a vehicle with excellent corrosion resistance and conductivity by forming a coating layer containing platinum (Pt) on the surface of the base material.

Specifically, in the step of forming a coating layer, a coating layer is formed by applying a current at a constant coating temperature using a coating material and an electrolyte. The choice of coating material is flexible as long as it contains platinum (Pt) and may be used as a coating material. However, for a more stable and efficient coating process, chloroplatinic acid (H₂PtCl₆) or potassium chloroplatinate (K₂PtCl₆) is preferred.

Platinum (Pt) and additional noble metal-based coating materials used as coating materials may be nanoparticles having a size of 10 nm to 1 μm. Within this size range, these materials may form a discontinuous coating layer of lower density on the surface of the base material.

As an electrolyte, an acidic electrolyte, for example, a sulfuric acid-based or hydrochloric acid-based electrolyte may be used, and in particular, H₂SO₄ or HCIO₄ is preferred in terms of efficient chemical reaction during the formation of the platinum coating layer of the process.

The content of the coating material and electrolyte may vary depending on the amount of Pt deposited and coating density required according to the specific embodiment. However, for example, a mixture of chloroplatinic acid (H₂PtCl₆) or potassium chloroplatinate (K₂PtCl₆) in the rang e of 1×10⁴ to 1 M and perchloric acid (HCIO₄) or sulfuric acid (H₂SO₄) in the range of 1×10⁻² to 1 M may be used. In particular, corrosion performance and contact resistance may be excellent when chloroplatinic acid (H₂PtCl₆) or potassium chloroplatinate (K₂PtCl₆) in the range of 2 mM to 0.1 M and perchloric acid (HClO₄) or sulfuric acid (H₂SO₄) in the range of 0.1 M to 0.5 M are used. It is more preferable when chloroplatinic acid (H₂PtCl₆) or potassium chloroplatinate (K₂PtCl₆) in the range of 10 mM to 0.05 M and perchloric acid (HClO₄) or sulfuric acid (H₂SO₄) in the range of 0.2 M to 0.3 M are used.

If the relative content of the coating material and the electrolyte within the above range is 1 to 10 times the unit molar content of the electrolyte, a coating layer with excellent corrosion performance and contact resistance may be formed. If the content is less than the above range, sufficient platinum (Pt) coating may not be achieved. Conversely, exceeding this range could lead to a decrease in the process's efficiency.

When chloroplatinic acid (H₂PtCl₆) or potassium chloroplatinate (K₂PtCl₆) as a coating material is used in the range of less than 5×10⁻³, it may be difficult to secure a sufficient amount of platinum (Pt) deposited. When the electrolyte is used in the range of less than 5×10⁻³, it may be difficult to secure sufficient reduction.

As a coating material, in addition to chloroplatinic acid or potassium chloroplatinate containing platinum, a coating material composed of precious metal-based components such as gold (Au), ruthenium (Ru), iridium (Ir), ruthenium oxide (RuO₂), and iridium oxide (IrO₂) may be additionally used. When an additional coating material is used, in addition to the sulfuric acid-based or hydrochloric acid-based electrolyte, a hydrofluoric acid-based or sulfuric acid-based electrolyte may be additionally used depending on the chemical properties of the added material.

The coating step may be performed even in a coating temperature of room temperature, but may be performed in the range of, for example, 25 to 80° C. in that reactivity may be improved through heating. Particularly, when the coating step is performed in the range of 40 to 60° C., corrosion performance and contact resistance are excellent while considering efficiency of a process, and particularly when the coating step is performed in the range of 50° C. to 60° C., corrosion performance and contact resistance are excellent.

It is preferably to perform the applied current during coating in the range of 5 to 60 mA/cm² in order to suppress uncoating or overcoating in an amount of platinum (Pt) deposited and to prevent surface oxidation due to overcurrent. In particular, for optimal surface stability of the base material and superior coating layer performance, it is preferable to perform in the range of 10 to 20 mA/cm².

The base material surface coating process method is not particularly limited as long as it is a commonly used method, but may be selected from, for example, electroplating, electroless plating, or a PVD method. Utilizing these methods can enhance the efficiency of the process. Particularly, electroplating is desirable for its ability to produce uniform coating properties and mass production in coating and manufacturing a separator cathode.

### Step of Thermal Treatment (S130)

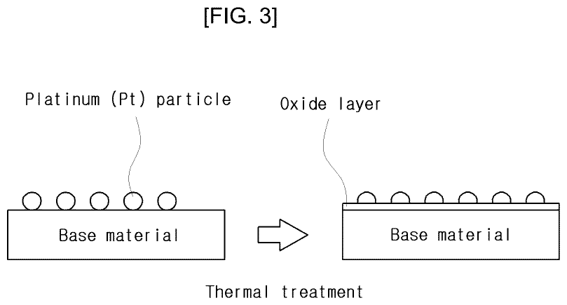

FIG. 3 schematically illustrates a step of thermal treatment of a base material on which the coating layer is formed.

In the step of coating a surface of a base material, since a discontinuous coating layer of platinum (Pt) and other materials is formed on the surface of the base material to expose part of the surface of the base material to the outside, a step of forming oxide layer (S130) is performed through a thermal treatment process to secure excellent corrosion current and contact resistance throughout the separator.

Specifically, the temperature of the thermal treatment process may vary depending on the oxide layer formation characteristics of the base material, but it may be performed, for example, in a temperature range of 80 to 600° C. In particular, in the temperature range of 170 to 230° C. for a stainless steel base material and 300 to 500° C. for a titanium base material, the oxide layer formation rate and oxide layer efficiency are excellent.

The time of the thermal treatment process may also vary depending on the characteristics of the base material. However, thermal treatment process may be performed, for example, for 10 to 180 minutes, and particularly, when performed for 30 to 60 minutes, the corrosion current and contact resistance performances of the oxide layer are excellent.

The thermal treatment process may be performed in a standard atmosphere, but when performed in a low-oxygen, vacuum, or nitrogen atmosphere, the oxide layer formation efficiency and the formed oxide layer performance may be improved. Specifically, performing the thermal treatment in a low-oxygen atmosphere is advantageous as it helps prevent the excessive formation of oxide layers, thereby ensuring optimal contact resistance and maintaining the adhesion quality of the coating.

### Metal Separator of Fuel Cell for Vehicle

According to the method of manufacturing the metal separator of a fuel cell for a vehicle, the metal separator of the fuel cell may have excellent corrosion resistance and electrical conductivity for an extended period of time even in a high temperature and high humidity operating environment.

Therefore, as described above, the metal separator of a fuel cell for a vehicle with excellent corrosion resistance and electrical conductivity may be subjected to a base material coating step using a coating material containing platinum (Pt) and an electrolyte and a thermal treatment step to complete the metal separator of a fuel cell for a vehicle in which a base material, a discontinuous coating layer on its surface, and an oxide layer on a part where the coating layer is not formed are formed.

### Examples and Comparative Examples

A base material forming step with the base material, coating material and electrolyte compositions, applied currents, and temperatures as shown in Table 1 below and a coating step were performed, and a thermal treatment step was performed on the base material on which the discontinuous coating layer was formed under the conditions in Table 2 to manufacture specimens of Examples and Comparative Examples, respectively.

Specifically, when compared to the Examples according to the present disclosure, in the coating material formation step, metal separator specimens were manufactured by changing the amount of coating material in Comparative Example 1, the amount of electrolyte in Comparative Example 5, and the applied currents in Comparative Examples 2 and 6, respectively, as shown in Table 1, and in the thermal treatment step, by changing the heat treatment time in Comparative Examples 3 and 6, and the heat treatment temperature in Comparative Examples 4 and 8, respectively as shown in Table 2.

TABLE 1

| | Base | | | Applied current | Temperature |
|---|---|---|---|---|---|
| Category | material | Coating material (M) | Electrolyte (M) | (mA/cm²) | (° C.) |
| Example 1 | SUS316L | 0.1 H₂PtCl₆ | 0.1 HClO₄ | 10 | 60 |
| Example 2 | | 0.1 H₂PtCl₆ | 0.1 HClO₄ | 20 | 60 |
| Example 3 | | 0.05 H₂PtCl₆ | 0.5 H₂SO₄ | 10 | 60 |
| Example 4 | | 0.02 K₂PtCl₆ | 0.1 HClO₄ | 20 | 40 |
| Example 5 | | 0.02 K₂PtCl₆ | 0.5 H₂SO₄ | 30 | 40 |
| Comp. | | 5 × 10⁻⁵ H₂PtCl₆ | 0.5 H₂SO₄ | 10 | 60 |
| Example 1 | | | | | |
| Comp. | | 0.1 H₂PtCl₆ | 0.1 HClO₄ | 3 | 60 |
| Example 2 | | | | | |
| Comp. | | 0.1 H₂PtCl₆ | 0.1 HClO₄ | 20 | 50 |
| Example 3 | | | | | |
| Comp. | | 0.1 H₂PtCl₆ | 0.1 HClO₄ | 20 | 60 |
| Example 4 | | | | | |
| Example 6 | Ti grade 1 | 0.1 H₂PtCl₆ | 0.1 HClO₄ | 10 | 60 |
| Example 7 | | 0.1 H₂PtCl₆ | 0.1 HClO₄ | 20 | 60 |
| Example 8 | | 0.05 H₂PtCl₆ | 0.5 H₂SO₄ | 10 | 60 |
| Example 9 | | 0.02 K₂PtCl₆ | 0.1 HClO₄ | 20 | 40 |
| Example 10 | | 0.02 K₂PtCl₆ | 0.5 H₂SO₄ | 30 | 40 |
| Comp. | | 0.1 H₂PtCl₆ | 0.05 HClO₄ | 20 | 60 |
| Example 5 | | | | | |
| Comp. | | 0.1 H₂PtCl₆ | 0.1 HClO₄ | 3 | 60 |
| Example 6 | | | | | |
| Comp. | | 0.1 H₂PtCl₆ | 0.1 HClO₄ | 20 | 60 |
| Example 7 | | | | | |
| Comp. | | 0.1 H₂PtCl₆ | 0.1 HClO₄ | 20 | 60 |
| Example 8 | | | | | |

TABLE 2

| | Thermal treatment | Thermal treatment time |
|---|---|---|
| Category | temperature (° C.) | (min) |
| Example 1 | 190 | 60 |
| Example 2 | 200 | 60 |
| Example 3 | 210 | 60 |
| Example 4 | 220 | 50 |
| Example 5 | 230 | 40 |
| Comp. Example 1 | 210 | 60 |
| Comp. Example 2 | 220 | 60 |
| Comp. Example 3 | 220 | 120 |
| Comp. Example 4 | 150 | 60 |
| Example 6 | 350 | 60 |
| Example 7 | 350 | 40 |
| Example 8 | 450 | 60 |
| Example 9 | 450 | 40 |
| Example 10 | 350 | 60 |
| Comp. Example 5 | 350 | 60 |
| Comp. Example 6 | 450 | 60 |
| Comp. Example 7 | 350 | 120 |
| Comp. Example 8 | 250 | 60 |

### Contact Resistance Measurement

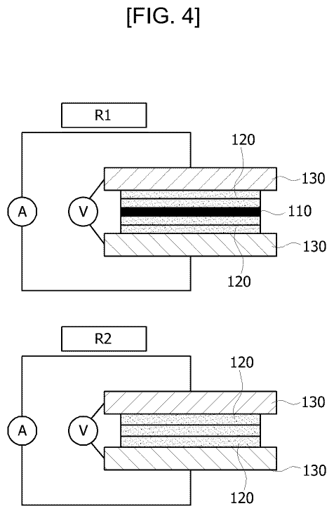

Interfacial contact resistance (ICR) was measured for Examples and Comparative Examples. FIG. 4 is a schematic diagram illustrating a structure of specimens for measuring the contact resistance of a metal separator of a fuel cell for a vehicle according to the present disclosure, and measurement positions of a comparative specimen (dummy). Prior to actual measurement, two gas diffusion layers (GDL) (120) and one current collector (130) were formed on both sides of the metal separator (bipolar plate: bp) (110) of each Comparative Example and Example to manufacture a specimen, and then the contact resistance between the separator and the gas diffusion layer (GDL) was measured at two points R1 and R2 and calculated according to the following equation to calculate the resistance between the separation and the gas diffusion layer. For R2 measurement, three gas diffusion layers (120) were stacked except for the metal separator, and a current collector (130) was stacked on both sides to manufacture a dummy specimen, and then, a pressure of 50 to 100 N/cm² was applied to the dummy using a pressure machine (68SC5, Instron Corporation) when measuring contact resistance.

$$R 1 = 2 {R}_{cc - GDL} + 2 {R}_{GDL - GDL} + 2 {R}_{bp - GDL}$$

$$R 2 = 2 {R}_{cc - GDL} + 2 {R}_{GDL - GDL}$$

$${R}_{bp - GDL} = ( R 1 - R 2 ) / 2$$

$$ICR = {R}_{bp - GDL} \times S$$

wherein bp refers to a metal separator, GDL refers to a gas diffusion layer, cc refers to a current collector, and S refers to a separator-GDL reaction area.

### Corrosion Performance Measurement

Specimens were manufactured from the metal separators of the above Examples and Comparative Examples, and short-term corrosion resistance evaluation of the base material and surface treatment layer was performed on each specimen. A potentiodynamic polarization method was conducted, and the test conditions are shown in Table 3 below. HIOKI's 3541 precision resistance measurement equipment was used as the current application and resistance measurement equipment.

TABLE 3

| Category | Description |
|---|---|
| Corrosive solution | 0.1N H₂SO₄ + 2 ppm HF |
| Solution temperature | Maintained at 80° C. |
| Working electrode | 1.0 cm² |
| Exposed area | |
| Reference electrode | Mercury sulfate electrode (MSE) |
| | SCE (@0.6 V vs SCE) |
| Counter electrode | Carbon electrode rod |
| Scan Rate | 1 mV/s |
| Scan Range | −0.25 V vs. OCV ~1.0 V |
| Evaluation standard | 10 μA/cm² or less |

The results of the interfacial contact resistance and corrosion performance measured as above are shown in Table 4 below.

TABLE 4

| | | Corrosion |
|---|---|---|
| | Interfacial contact | performance |
| Category | resistance (mΩ · cm²) | (μA/cm²) |
| Example 1 | 8.3 | 2.5 |
| Example 2 | 9.7 | 1.8 |
| Example 3 | 9.9 | 1.5 |
| Example 4 | 8.9 | 1.9 |
| Example 5 | 9.8 | 1.3 |
| Comp. Example 1 | 20.1 | 3.3 |
| Comp. Example 2 | 28.2 | 1.2 |
| Comp. Example 3 | 42.9 | 0.8 |
| Comp. Example 4 | 7.8 | 13.1 |
| Example 6 | 11.2 | 2.2 |
| Example 7 | 9.3 | 2.4 |
| Example 8 | 12.6 | 0.8 |
| Example 9 | 11.7 | 1.2 |
| Example 10 | 10.6 | 2.5 |
| Comp. Example 5 | 18.6 | 4.5 |
| Comp. Example 6 | 33.2 | 3.1 |
| Comp. Example 7 | 38.5 | 0.7 |
| Comp. Example 8 | 9.8 | 11.1 |

For Comparative Examples and Examples, a steering rack bar was manufactured to perform a cold drawing test, and the product was visually observed for cracks occurred and the results are shown in Table 4.

Referring to Tables 1 to 4, in Examples 1 to 5 and Comparative Examples 1 to 4 using a stainless base material and Examples 6 to 10 and Comparative Examples 5 to 8 using a titanium base material, each Example was found to be excellent in terms of corrosion performance and interfacial contact resistance compared to the Comparative Examples.

Specifically, it was confirmed that when the amount of electrolyte or coating material was out of the range of the present disclosure, the performance was significantly degraded compared to other Examples using the same base material in terms of both interfacial contact resistance and corrosion performance, and it was confirmed that when the applied current and coating temperature are out of a certain range, the performance of the interfacial contact resistance was degraded, which means that appropriate coating process conditions have a significant impact on achieving the purpose of the present disclosure.

Even in the step of thermal treatment, it was found that the thermal treatment temperature and thermal treatment time had an effect on the interfacial contact resistance and corrosion performance, respectively. In particular, it was confirmed that the thermal treatment time had a significant effect in terms of interfacial contact resistance, and the thermal treatment temperature had a significant effect in terms of corrosion performance.

Although the above description focuses on the embodiments of the present disclosure, various changes and modifications can be made at the level of those skilled in the art. It can be said that these changes and modifications belong to the present disclosure as long as they do not depart from the scope of the present disclosure. Therefore, the scope of the present disclosure should be determined by the claims set forth below.

### INDUSTRIAL APPLICABILITY

The present disclosure may be utilized in the field of fuel cells and in the field of separators for a fuel cells, and can improve the reliability and competitiveness of products in these fields.

What is claimed is:

1. A method for manufacturing a metal separator of a fuel cell for a vehicle the method comprising steps of:
preparing a base material;
applying a platinum (Pt)-containing coating agent and an electrolyte on the base material to form a discontinuous coating layer; and
thermally treating the base material and the coating layer to form on an oxide layer on the base material.

2. The method of claim 1, wherein the platinum (Pt)-containing coating agent further comprises gold (Au), ruthenium (Ru), iridium (Ir), ruthenium oxide (RuO₂), or iridium oxide (IrO₂).

3. The method of claim 1, wherein the base material is stainless steel, titanium, aluminum or polymer composite material.

4. The method of claim 1, wherein the step of forming the discontinuous coating layer is performed through electroplating, electroless plating, or a PVD process.

5. The method of claim 1, wherein chloroplatinic acid (H₂PtCl₆) or potassium chloroplatinate (K₂PtCl₆) is contained as platinum (Pt) contained in the platinum (Pt)-containing coating agent.

6. The method of claim 1, wherein the step of thermally treating is performed in a temperature range of about 80 to 600° C.

7. The method of claim 6, wherein the base material is stainless steel, and wherein the step of thermally treating is performed in a temperature range of about 170 to 230° C.

8. The method of claim 6, wherein the base material is titanium, and wherein the step of thermally treating is performed in a temperature range of about 300 to 500° C.

9. The method of claim 6, wherein the step of thermally treating is performed in a time range of about 10 to 180 minutes.

10. The method of claim 9, wherein the step of thermally treating is performed in a time range of about 30 to 60 minutes.

11. The method of claim 1, wherein the step of thermally treating is performed under vacuum, air, or oxygen atmosphere.

12. The method of claim 1, wherein the electrolyte is an acidic electrolyte.

13. The method of claim 12, wherein the acidic electrolyte is a sulfuric acid-based or hydrochloric acid-based electrolyte.

14. The method of claim 13, wherein the sulfuric acid-based electrolyte is H₂SO₄.

15. The method of claim 13, wherein the hydrochloric acid-based electrolyte is HClO₄.

16. The method of claim 1, wherein the step of applying a platinum (Pt)-containing coating agent and an electrolyte on the base material comprises applying a current at a coating temperature.

17. The method of claim 16, wherein the current is about 5 to 60 mA/cm².

18. The method of claim 16, wherein the coating temperature is about 25 to 80° C.

19. A metal separator of a fuel cell for a vehicle manufactured by the method of claim 1.

20. A vehicle comprising a fuel cell that comprises the metal separator manufactured by the method of claim 1.
